(19) United States
(12) Patent Application Publication
(10) Pub. No.: US 2011/0117681 A1
(43) Pub. Date: May 19, 2011

(54) THIN FILM IMAGING METHOD AND APPARATUS

(75) Inventors: Robert Andrew Bardos, New South Wales (AU); Thorsten Trupke, New South Wales (AU); Ian Andrew Maxwell, New South Wales (AU)

(73) Assignee: BT IMAGING PTY LTD, Surry Hills, New South Wales (AU)

(21) Appl. No.: 13/002,748

(22) PCT Filed: Jul. 9, 2009
(86) PCT No.: PCT/AU09/00886

§ 371 Date: Jan. 5, 2011

(30) Foreign Application Priority Data
Jul. 9, 2008 (AU) 2008903538

(51) Int. Cl. H01L 21/66; G01J 1/58

(52) U.S. Cl. 438/7; 250/458.1; 257/E21.526; 250/208.1

(57) ABSTRACT

Methods and apparatus are presented for monitoring the deposition and/or post-deposition processing of semiconductor thin films using photoluminescence imaging. The photoluminescence images are analysed to determine one or more properties of the semiconductor film, and variations thereof across the film. These properties are used to infer information about the deposition process, which can then be used to adjust the deposition process conditions and the conditions of subsequent processing steps. The methods and apparatus have particular application to thin film-based solar cells.

### FIELD OF THE INVENTION

The present invention relates to imaging properties of thin films and, in particular, discloses a method and apparatus for photoluminescence imaging of semiconductor thin films, especially for thin film-based photovoltaic cells. However it will be appreciated that the invention is not limited to this particular field of use.

### BACKGROUND

Any discussion of prior art throughout the specification should in no way be considered as an admission that such prior art is widely known or forms part of the common general knowledge of the field.

Thin film deposition includes techniques for depositing a thin film of material onto a substrate or onto previously deposited layers. ‘Thin’ is a relative term, but most deposition techniques allow layer thickness to be controlled within a few tens of nanometres, and some such as molecular beam epitaxy allow single layers of atoms to be deposited at a time.

Thin films are useful in the manufacture of optics (for reflective or anti-reflective coatings for instance), electronics (e.g. layers of insulators, semiconductors and conductors for integrated circuits), optoelectronics (e.g. III-V LEDs and laser diodes), packaging (e.g. aluminium-coated PET film), and in contemporary art. In many of these applications the thickness and quality of the deposited films are important if not crucial properties. In other applications such as purification of copper by electroplating and deposition of silicon and enriched uranium by a CVD-like process after gas-phase processing, film thickness is not important.

Deposition techniques fall into two broad categories, depending on whether the process is primarily chemical or physical. Chemical deposition is where a fluid precursor undergoes a chemical change at a solid surface, leaving a solid layer. Since the fluid surrounds the solid object, deposition happens on every surface with little regard to direction, so that thin films from chemical deposition techniques tend to be conformal rather than directional. Chemical deposition is further categorised by the phase of the precursor: plating and chemical solution deposition (CSD) rely on liquid precursors, whereas chemical vapour deposition (CVD) generally uses gas-phase precursors. Plasma-enhanced CVD (PECVD) uses an ionised vapour, or plasma, as a precursor. Physical deposition on the other hand uses mechanical or thermodynamic means to produce a thin film of solid material. Deposition techniques can also be characterised by the temperature at which they are performed. For example techniques performed at or below room temperature may be described as ‘cold’ whereas those performed at elevated temperatures may be described as ‘hot’.

Many of the above deposition processes are extremely expensive and also extremely slow. For example a multi-layer III-V thin film stack grown by PECVD may take five hours to grow in an expensive high vacuum deposition chamber. Because of the high voltage and high temperature in the growth chamber there are limited options to assess the quality of the growing film, and hence it is difficult to assess quality until after the sample is finished (by which time the cost has been incurred).

One technique for characterising semiconductor thin films, such as GaN, InGaN and AlGaN films in blue/green LEDs, is photoluminescence (PL) mapping. PL mapping is typically used to monitor composition and lattice defects, and available tools (such as the VerteX™ instrument from Nanometrics) typically scan a focussed excitation laser beam across a sample in point-by-point fashion and measure the intensity and spectral content (especially the peak emission wavelength) of the resulting PL. As disclosed in published PCT patent application No WO 2004/010121 A1 and published US patent application No 2007/0000434 A1, PL mapping has also been used to characterise thin films of the indirect semiconductor SiGe grown on silicon for integrated circuit applications.

Despite its undoubted value for thin film characterisation, the point-by-point nature of PL mapping causes it to be a relatively slow technique, with a measurement time of the order of 30 seconds to several minutes depending on the sample area and the point spacing. While this may be acceptable for characterising multi-layer thin film stacks that take several hours to grow, it is likely to be a limitation for routine or in-line characterisation of single layer thin films for the photovoltaic (or solar) cell industry for example. Further, the intensity of the focussed excitation laser light used in PL mapping is also orders of magnitude greater than the 1 Sun illumination intensity (˜100 mW/cm²) experienced by photovoltaic cells in operation, and will thus give an unrealistic picture of the expected performance of thin film-based photovoltaic cells.

The relative slowness of PL mapping also limits its suitability for in-situ monitoring of thin film growth, since it may be unable to feed information back into the deposition process sufficiently quickly to arrest or correct a problem.

### SUMMARY

It is an object of the present invention to overcome or ameliorate at least one of the disadvantages of the prior art, or to provide a useful alternative. It is an object of the present invention in its preferred form to provide a method and apparatus for effective monitoring of thin film deposition techniques.

In accordance with a first aspect of the present invention, there is provided a method of monitoring a thin film deposition process, the method comprising the steps of: (a) illuminating with a predetermined illumination an area of a semiconductor thin film grown or being grown by the deposition process, to produce photoluminescence from the thin film; (b) capturing an image of the photoluminescence; (c) processing the image to determine one or more properties of the thin film; and (d) using the one or more properties to infer information about the deposition process.

The method can be performed while the thin film can be being grown by the deposition process. When the deposition process occurs within a chamber, the thin film can be illuminated through a window of the chamber transparent to the predetermined illumination, and the image can be captured through a window of the chamber transparent to the photoluminescence. Steps (a) and (b) are preferably repeated to generate a photoluminescence image of a larger area of the thin film.

Preferably, the method can be utilised to determine the spatial variation of at least one of the following properties: absorber layer quality; minority carrier lifetime; homogeneity of layer composition in compound materials; impurity concentration; concentration of electrical defects; and concentration of structural defects. Preferably, the method can be utilised to monitor the production of thin film-based photovoltaic cells or modules. The method can also be utilised to monitor at least one of: minority carrier lifetime variations; local voltage variations upon illumination; local shunted areas or shunted individual cells in an interconnected module; or series resistance problems in a cell or module.

The method further can comprise the step of (e) utilising the information determined in step (d) to adjust the thin film deposition process. Step (e) preferably can include at least one of: removal of thin film samples; adjustment of a processing condition; or detection of a hardware fault in the deposition process. The method further can comprise the step of (f) utilising the information determined in step (d) to adjust or control post-deposition processing of the thin film.

The post-deposition processing preferably can include annealing, hydrogenation, diffusion, laser isolation of a defective area, metallisation, module interconnection, or reprocessing of the thin film. The photoluminescence preferably can include the band-to-band luminescence of the semiconductor thin film. The photoluminescence preferably can include luminescence emitted by impurities and defects in the semiconductor thin film.

In accordance with a further aspect of the present invention, there is provided a method of monitoring a partially or fully completed semiconductor thin film photovoltaic cell or module, the method comprising the steps of: (a) illuminating with a predetermined illumination an area of the semiconductor thin film photovoltaic cell or module, to produce photoluminescence from the cell or module; (b) capturing an image of the photoluminescence; (c) processing the image to determine one or more properties of the cell or module; and (d) using the one or more properties to infer information about cell or module.

The information gathered preferably can include the spatial variation of at least one of the following properties: absorber layer quality; minority carrier lifetime; homogeneity of layer composition in compound materials; impurity concentration; concentration of electrical defects; and concentration of structural defects. The information preferably can also include local voltage variations upon illumination; local shunted areas or shunted individual cells in an interconnected module; or series resistance problems in a cell or module.

Preferably, the method also includes the steps of: (e) utilising the information determined in step (d) to adjust the process used to deposit the thin film in the semiconductor thin film photovoltaic cell or module. Preferably, the step (e) preferably can include at least one of: removal of thin film samples; adjustment of a processing condition; or detection of a hardware fault in the deposition process. Preferably, the method can also comprise the step of (f) utilising the information determined in step (d) to adjust or control further processing of the semiconductor thin film photovoltaic cell or module. The further processing preferably can include annealing, hydrogenation, diffusion, laser isolation of a defective area, metallisation, module interconnection, or reprocessing of the thin film. The method can preferably also include the step of (g) predicting the performance of a finished semiconductor thin film photovoltaic cell or module.

### BRIEF DESCRIPTION OF THE DRAWINGS

Embodiments of the invention will be better understood and readily apparent to one of ordinary skill in the art from the following written description, by way of example only, and in conjunction with the drawings:

FIG. 1 illustrates schematically one arrangement for photoluminescence monitoring of a thin film; and

FIG. 2 illustrates one form of processing steps for the preferred embodiment.

### DETAILED DESCRIPTION OF THE PREFERRED AND OTHER EMBODIMENTS

In certain preferred embodiments there is provided a method and apparatus for effective monitoring of thin film deposition techniques and using the resultant data to control the thin film deposition process either in real time or in preparation for the next samples to be processed. The method and apparatus also provide for effective measuring of thin film material and electronic properties during or after one or more of the initial thin film deposition steps and subsequent processing steps, for quality control and process improvement.

Other preferred embodiments, of particular relevance to photovoltaic cells, allow for effective monitoring or control of subsequent post-deposition processing steps, such as annealing, hydrogenation, metallisation, laser isolation (e.g. of defective areas) and module interconnection (e.g. using a laser), or to predict the performance of photovoltaic cells or modules.

In preferred embodiments, there is provided a method of monitoring the condition of a thin film deposition process, the method comprising the step of measuring the PL properties of the bulk or surface properties of the thin film to determine electrical or material characteristics thereof. The preferred embodiments also provide a method of monitoring the condition of post-deposition processing steps, the method comprising the step of measuring the PL properties of the bulk or surface properties of the thin film.

In certain embodiments the PL is measured in a simple area-averaged measurement with illumination of a substantial portion of the thin film sample. In preferred embodiments the PL is measured in a multi-pixel spatially resolved image of a substantial portion of the thin film sample, e.g. with a CCD camera. In this case each camera pixel measures the PL response from a small area of the sample, allowing rapid assessment of PL variations across the sample that can be related to variations in material or electrical properties of the sample. The PL signal can arise from band-to-band luminescence of the semiconductor material itself, or from impurities or defects in the deposited semiconductor material.

In one preferred embodiment the thin film deposition process is monitored in-situ by PL measurements with an excitation light source and detector placed externally to the deposition chamber, monitoring the thin film though a window of the chamber. The method preferably includes analysing spatially resolved PL images of a thin film sample to infer spatial variations of key semiconductor material properties, such as composition and defect density, to ensure the semiconductor material is of sufficient quality. Because PL intensity may be related to film thickness for a known semiconductor, the method can also be used to measure film thickness and spatial variations thereof by direct correlation with the PL intensity in a given area, or by a combination method with other optical measurements. The method can be used for both direct and indirect bandgap materials, including silicon, GaN, CIGS, CdTe, CIS and GaAs. For compound semiconductors PL imaging can be used to check and/or control the stoichiometry of the deposited films.

In preferred embodiments the method is utilised to monitor the spatial variation of at least one of: absorber layer quality (particularly minority carrier lifetime) and lateral variations thereof; homogeneity of layer composition in compound materials; impurity concentrations and lateral variations thereof; and concentration of structural and electrical defects and lateral variations thereof

Minority carrier lifetime is a key property of photovoltaic materials, and although it may not always be of interest for the performance of thin film semiconductor devices in other fields of use it can be used as a proxy for other semiconductor material properties. The method is applicable to semiconductor thin films with either n-type or p-type background doping.

In preferred embodiments the method is utilised to monitor thin film photovoltaic cells, and in particular to monitor several material or electrical properties including variations in material quality (particularly minority carrier lifetime) and defects and other local features that reduce minority carrier lifetime, variations in local voltage upon illumination, local shunted areas or shunted individual cells in an interconnected module, and series resistance problems such as faulty interconnections between cells in a module.

The method can be utilised to control or adjust a thin film deposition process in real time (i.e. with in-situ monitoring of the deposition process) or using information obtained from a sample post-deposition, or to control or adjust a subsequent post-deposition process step. The process control or adjustment preferably includes at least one of: removal of thin film samples; adjustment of processing conditions (e.g. film deposition and post-deposition annealing, hydrogenation or diffusion), sample-specific subsequent processing (e.g. to correct a defect), reprocessing of the same sample, metallisation, laser isolation of individual cells or of defective areas, module interconnection, or detection of faults in manufacturing hardware.

In one preferred embodiment there is provided a method for monitoring thin film growth through PL imaging. The method can be embodied in an apparatus that relies on an entirely optical measurement that is non-contact and hence suitable for inclusion into most thin film growth processes. Unlike the PL mapping techniques currently used to characterise thin films, PL imaging is quick and hence can measure key properties continuously whilst growth is occurring, enabling process control or sample rejection in real time.

Further, the active components (a light source and camera) can be placed entirely outside the active growth chamber and the thin film can be monitored through optically clear windows.

Certain preferred embodiments utilise PL imaging of thin films to provide process feedback for a manufacturing system. PL imaging systems similar to those described in published PCT patent application No. WO 2007/041758 A1 entitled ‘Method and System for Inspecting Indirect Bandgap Semiconductor Structure’, the contents of which are hereby incorporated by cross reference, can be utilised to perform the preferred embodiments.

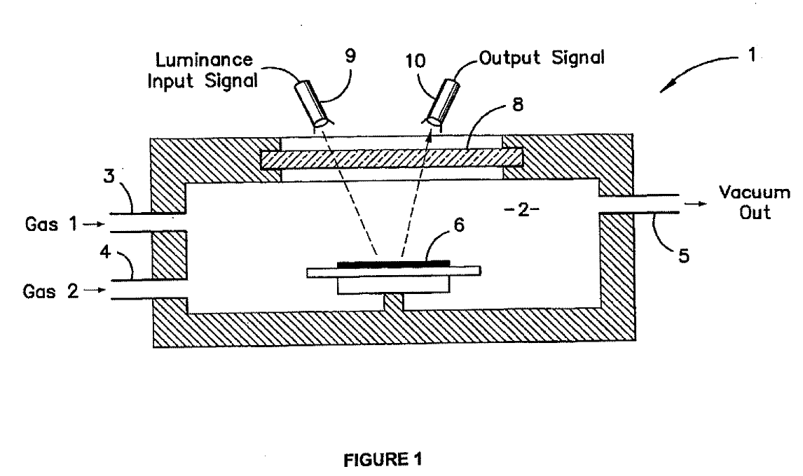

In one preferred embodiment, a CVD type deposition device is modified so that PL imaging of a thin film substrate can occur during growth so as to monitor the operational conditions of the thin film growth process. An example of a suitable arrangement 1 is illustrated schematically in FIG. 1. In this arrangement, a CVD chamber 2 is provided for the deposition of a semiconductor material derived from constituents injected through gas input ports 3, 4. A vacuum port 5 is also provided for evacuating the chamber or for out-gassing. Deposition of a thin film of semiconductor material 7 occurs onto a substrate 6.

The deposition process is monitored through a transparent glass window 8 by a PL imaging system comprising a light emission source 9 (e.g. a lamp, laser or LED type device depending on requirements) and a spatial photodetector 10 such as a CCD camera. The photodetector spatially images the thin film 6 under the illumination conditions of the light source and outputs a corresponding spatial image to a computerised PL processing and control system. The PL imaging system may also contain several other elements such as collimation optics, a homogeniser and optical filters (e.g. short-pass, band-pass and long-pass filters), as described in the abovementioned published PCT patent application No WO 2007/041758 A1. In the embodiment shown in FIG. 1, the thin film sample is illuminated and the PL emission acquired through the same window 8, which obviously needs to be transparent at the illumination and PL wavelengths. In alternative embodiments the sample can be illuminated and the PL imaged through separate windows, each of which only needs to be transparent at the appropriate wavelength band. This arrangement could reduce the number of separate optical filters required in the PL optics.

It is recognised that for ‘hot’ deposition processes the sample may be effectively ‘glowing’, with thermal emission obscuring or even swamping any PL signal. This ‘noise’ can be ameliorated to some extent by using lock-in detection techniques (i.e. modulating the light source and detecting PL emission at the modulation frequency). The extent to which thermal emission is a problem for in-situ PL monitoring will also depend on the wavelength of the PL generated by the sample. For example, the near-IR PL emission from silicon (around 900 to 1250 nm) is more likely to be affected by thermal emission at a given temperature than the blue-green emission from III-V semiconductors such as GaN. Direct bandgap semiconductors, with orders of magnitude greater luminescence efficiency than indirect bandgap semiconductors, are also expected to be more amenable to in-situ monitoring of ‘hot’ deposition processes. For ‘cold’ deposition processes there is no thermal noise problem to be overcome.

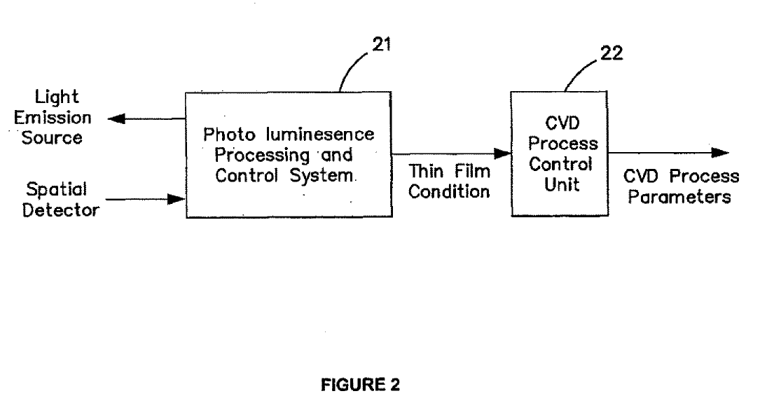

Turning now to FIG. 2, there is illustrated schematically the processing steps in an example CVD processing system. The light emission source 9 and spatial photodetector 10 act under the control of a PL processing and control system 21 that controls the light emission and spatially images the PL emitted by the sample thin film. From image processing of the results, a determination of the condition of the thin film is made and outputted to a CVD process control unit 22 that controls the CVD process e.g. by manipulating process parameters such as gas flow rates and chamber temperature so as to improve the CVD process. The processing steps shown in FIG. 2 apply to embodiments where film growth is monitored in-situ as well as to embodiments where films are monitored post-deposition.

The PL imaging technique can be used by the PL processing and control system 21 to measure several properties of a growing or completed film, including absorber layer quality (e.g. minority carrier lifetime) and lateral variations thereof, homogeneity of layer composition in compound materials, impurity concentration and lateral variations thereof, and concentration of structural and electrical defects and lateral variations thereof. These are key properties for thin films grown for photovoltaic cell applications and also for other semiconductor, display and LED applications.

Most industrial semiconductors and photovoltaic cells to date are manufactured on silicon wafers with a thickness of typically 150 μm to 400 μm, with a current trend in photovoltaic cells in particular towards thinner wafers. Thin film photovoltaic cells, also referred to as ‘second generation photovoltaics’ are a specific subset of photovoltaic devices where a thin layer of absorber material forms the ‘heart’ of the device. One general characteristic of thin film photovoltaics is that the thin absorber layer is often deposited/mounted on or attached to a foreign substrate, whereas in wafer-based cells the wafer itself forms both the absorber and the structural support. Typical absorber thicknesses in thin film photovoltaic cells range from ˜100 nm to several micrometres. A significant advantage of thin film photovoltaic cells over traditional wafer-based cells is that two to three orders of magnitude less absorber material is required, offering significantly reduced cost. Another advantage is that thin film processing technology allows series and parallel interconnected modules to be processed directly on large area foreign substrates, removing the requirement to first process individual cells and then interconnect them into modules in a separate step.

Materials deposited as absorbers in thin film photovoltaic cells include amorphous silicon (a-Si), amorphous silicon-germanium alloys (a-SiGe), crystalline silicon (c-Si), crystalline silicon-germanium alloys (c-SiGe), crystalline germanium (c-Ge), Cu(In,Ga)Se₂ (CIGS), CdTe, III-V semiconductors based on gallium, aluminium and indium arsenide (Al(In,Ga)As), organic compounds such C-60 molecules in combination with other organic semiconductors, and dye molecules.

Most crystalline silicon thin film deposition techniques produce multicrystalline films. Depending on the grain size, different types of c-Si can be distinguished such as nanocrystalline Si, microcrystalline Si and polycrystalline Si. Development of some of the above material systems is either at the R&D stage in universities or other research organisations or at an early stage of commercialisation. Significant scale industrial manufacturing is at present limited to a-Si modules, CdTe modules, tandem cells made from c-Si and a-Si (the so-called micromorph cell), CIGS modules and c-Si on glass.

Some of the important common features and characteristics that need to be monitored in thin film absorber layers include absorber layer quality (especially minority carrier lifetime) and lateral variations thereof, homogeneity of layer composition in compound materials, impurity concentration and lateral variations thereof, and concentration of structural defects and lateral variations thereof. In addition, manufacturers are constantly trying to increase the rate of film deposition, which improves the cost-competitiveness of these technologies but also has direct quality impact on the important common features and characteristics described above.

Important common features and characteristics that need to be monitored in thin film photovoltaic cells and interconnected modules include material quality (especially minority carrier lifetime) variations, local voltage variations upon illumination, local shunted areas or shunted individual cells in an interconnected module, and series resistance problems such as faulty interconnections between cells in a module.

The imaging of luminescence, either PL or electroluminescence (EL), is an efficient metrology tool for process monitoring and characterisation of large area c-Si wafers and c-Si wafer based solar cells, and even entire c-Si wafer solar cell based modules. Luminescence imaging measures the lateral distribution of the luminescence intensity, which is then analysed to identify local parameters such as the local minority carrier lifetime or electrical cell parameters across the sample area. In PL and EL imaging, the luminescence is generated by photo-excitation or electrical excitation respectively, and a camera is used for detection. Samples can also be excited by a combination of illumination (photo-excitation) and applied voltage (electrical excitation).

Several alternative methods exist where lateral variations of specific parameters are measured in a scanning type methodology, e.g. point-by-point as in PL mapping or microwave photoconductance decay (μ-PCD) mapping, or with an array of sensors in a line-scanner. The spatial resolution achieved in practice with these types of instruments is often limited by the time available for a scan, i.e. the higher the spatial resolution for a specific measurement area the longer the measurement takes. Another disadvantage is that in such techniques only a small area is illuminated, generally with a focussed laser beam. As a result, the experimental conditions do not represent typical operating conditions of the material under test, for example the 1 Sun operating conditions of a photovoltaic cell.

Advantages of PL imaging (as opposed to mapping), particularly in photovoltaics, are that high resolution images can be achieved in a short time of typically only a few seconds or even fractions of a second, and illumination conditions can be close to the typical operating conditions of 1 Sun illumination, i.e. typically ˜100 mW/cm² for illumination in the NIR spectral range (e.g. λ_{exc}=900 nm). For shorter wavelength excitation in the visible or UV range the illumination can be adapted to yield an absorbed photon flux that is similar to the absorbed photon flux under 1 Sun illumination.

In one embodiment, high resolution images of entire large area thin film layers/modules are obtained by illumination of and detection from the entire layer/module. The spatial resolution in the image is then limited by the detector resolution (number of pixels) and the module area. Photovoltaic modules can be greater than 1 m² in size, and to achieve an incident intensity of ˜100 mW/cm² over that area a cw-light source with >10 kW output power would be required. In an alternative embodiment suitable for large area samples, an entire luminescence image can be generated by stitching together images acquired sequentially from subsections that may be 1×1 cm² to 20×20 cm² in size, not limited to square shaped areas. Light sources with much smaller total output power can then be used and much higher spatial resolution can be achieved. The trade-off is longer total data acquisition time and the requirement to scan the sample mechanically relative to the illumination/detection system. Depending on requirements, the following scanning methods can be utilised: ‘step and image’, where a small area section is imaged and either the substrate or the imager is moved onto the next section; ‘scan and image’, where the imager measures a fixed small area unit but is constantly in movement sweeping back and forth relative to the sample; or ‘sweep imaging’, where for example a line imager the full width of a thin film sample is moved lengthwise relative to the sample.

In some respects, PL imaging on thin film layers, and in particular on thin film photovoltaic cells and modules composed of direct bandgap semiconductors, can be significantly easier than PL imaging on wafers and traditional photovoltaic cells based on c-Si. PL imaging of silicon wafers is challenging because c-Si is an indirect bandgap material and as such generally has a very low luminescence quantum efficiency, typically of order <10⁻⁴. Also, the emission from c-Si is in the wavelength range 900-1250 nm, so that a large fraction of the emission spectrum is outside the spectral range where silicon cameras are sensitive.

For most of the abovementioned thin film semiconductor materials, the bandgaps are at higher energies compared to silicon, corresponding to shorter wavelengths more suitable for detection with conventional Si cameras (CCD, CMOS). In addition, the luminescence quantum efficiency of direct bandgap materials is generally orders of magnitude higher, resulting in higher luminescence intensity for the same illumination conditions, and absorbing coloured glass filters are available (e.g. from Schott) in small spectral intervals from the UV to the NIR (850 nm).

In specific cases, i.e. on materials such as SiGe with smaller bandgap than Si, PL detection will require an alternative detector technology such as an InGaAs camera.

For each material system, the emission and absorption properties will be different, requiring the illumination wavelength and optical filters to be chosen specifically. Generally, the illumination source needs to be short-pass filtered to prevent any illumination light reflected by the sample or the surrounds from being detected by the camera. Furthermore, a long-pass filter is required in front of the camera optics. The cut-off wavelengths of the filters need to be chosen for the specific excitation and luminescence wavelengths.

In alternative embodiments, a combination of photo-excitation and electrical excitation can be used, for example PL imaging with external control of the voltage between the contact terminals of a finished or near-finished thin film photovoltaic cell. Samples (e.g. entire modules or partially processed layers on a substrate) can be measured by either imaging the entire sample or by mechanically scanning the surface with several individual images as described above. An application of dual excitation to the characterisation of traditional c-Si photovoltaic cells is described in published PCT patent application No WO 2007/128060 A1 entitled ‘Method and System for Testing Indirect Bandgap Semiconductor Devices Using Luminescence Imaging’, the contents of which are hereby incorporated by cross reference. In this application a sample cell is illuminated (typically with 1 Sun equivalent illumination) and then biased to a voltage that is smaller than the open circuit voltage at that illumination. Under these conditions, bright areas in the emission are indicative of areas of enhanced series resistance or electrically isolated areas. In the context of thin film photovoltaic cell samples, this information could be fed back into adjusting the deposition conditions or the conditions of subsequent processing steps.

General applications include in-line process monitoring and process control via measurement of the lateral variation of the material quality after key processing steps, or measurement of lateral variations in key photovoltaic cell parameters such as the series and parallel resistance.

Process control can include removal of defective samples from the line at an early stage, adjustment of processing conditions such as film deposition or post-deposition annealing, hydrogenation and diffusion, sample-specific subsequent processing (e.g. to correct a defect by laser isolation of bad areas for example), reprocessing of the same sample, metallisation, laser isolation of individual cells or of defective areas, module interconnection, and detecting faults in manufacturing hardware.

A number of specific applications are envisaged. For example in composite materials the emission wavelength and the intensity distribution across the spectrum will depend on the composition of the material. This is particular important in CIGS materials where the functioning of a photovoltaic cell depends critically on the stoichiometric distribution of the four elemental components across the layer. In SiGe alloys (crystalline or amorphous) the emission wavelength shifts towards longer wavelength with higher Ge content, so that lateral variations of the film stoichiometry can be inferred from corresponding variations of the emission spectrum. Comparison (e.g. by ratio, difference or derivative) of two or more PL images measured with different spectral filters (e.g. long-pass, short-pass or band-pass) mounted in front of the camera objective can therefore be used to obtain information about variations in the film composition. For example there may be regions where one specific component of the film precipitates/crystallises into an area of elemental semiconductor material with a characteristic emission spectrum that could be analysed using PL images acquired with suitable filters. A large range of suitable band-pass, long-pass and short-pass filters that can be used for this purpose are readily available. While filter combinations cannot give the same level of spectral discrimination offered by spectrometer-equipped PL mapping systems, they are simpler, less expensive and more suitable to the rapid PL imaging. Furthermore there will be many situations where the spectral changes caused by composition variations will be sufficiently large to be detected by changing filter combinations.

In thin film photovoltaic cell modules, different parts of the module are often connected in series and/or in parallel to each other, often via laser processing. PL image analysis of a partially processed module may detect local areas of significantly degraded material quality or shunted regions that would result in areas within the module that generate less voltage and/or current than other areas. If defective areas are detected, a number of actions can be taken. For example the interconnection of the module can be modified to avoid connection of the worst quality regions, or the interconnection may be optimised with regard to the series and parallel interconnection of different parts of the module. A simplified example of how this could work is as follows: for a module where one half of the area consists of good quality material providing 1.0V open circuit voltage and the other half consists of poor quality material providing only 0.8V open circuit voltage, the interconnection can be carried out in such a way that four cells from the good quality region are connected in series and five cells from the poor quality region are connected in series. These two voltage matched series-connected strings can then be connected in parallel, so that the material is used more efficiently overall. Ordinarily, five cells from each side would be series-connected, and the lower voltage of the poor quality region would unnecessarily reduce the voltage of the good quality area.

In tandem photovoltaic cells at least two cells made from different materials are normally located on top of each other, i.e. optically in series, and series-connected in monolithic fashion. The material at the top of the stack has the largest bandgap so that it absorbs high energy (shorter wavelength) photons and transmits lower energy photons, so that subsequent layers with increasingly lower energy bandgaps will absorb portions of the incident spectrum with increasingly longer wavelengths. Specific wavelengths are thus ideally absorbed only in specific cells in the stack. For characterisation purposes PL imaging can be used to excite one or several individual layers selectively with suitable monochromatic or bandpass-filtered light, and then detect the luminescence emission only from those one or several individual layers. The above series resistance analysis can be carried out by biasing the entire stack and illuminating only specific cells with the appropriate excitation wavelengths.

Beneficial in this context is the fact that luminescence emission is normally at longer wavelengths than the excitation wavelength. Emission from the n-th cell in a stack is able to propagate through the overlying n−1 cells and be detected, because these cells all have larger band gaps than cell n and are therefore transparent to the emission from cell n.

In thin film c-Si the emission of band-to-band luminescence is extremely weak due to the poor material quality, the indirect band gap of c-Si and the small emission volume compared to a wafer. As an alternative, the broad emission from decorated dislocations (i.e. dislocations containing impurities) can be utilised. This emission band has its peak at wavelength ˜1550 nm which cannot be detected with a silicon camera, but could be detected with an InGaAs camera. Imaging of defect-related photoluminescence from thin film c-Si modules and layers can therefore be used as a quality control technique.

Although the invention has been described with reference to specific examples it will be appreciated by those skilled in the art that the invention may be embodied in many other forms.

1. A method of monitoring a thin film deposition process, said method comprising the steps of:
(a) illuminating with a predetermined illumination an area of a semiconductor thin film grown or being grown by said deposition process, to produce photoluminescence from said thin film;
(b) capturing an image of said photoluminescence;
(c) processing said image to determine one or more properties of said thin film; and
(d) using said one or more properties to infer information about said deposition process.

2. A method as claimed in claim 1 wherein said method is performed while said thin film is being grown by said deposition process.

3. A method as claimed in claim 2 wherein said deposition process occurs within a chamber, said thin film is illuminated through a window of said chamber transparent to said predetermined illumination, and said image is captured through a window of said chamber transparent to said photoluminescence.

4. A method as claimed in claim 1 wherein steps (a) and (b) are repeated to generate a photoluminescence image of a larger area of said thin film.

5. A method as claimed in claim 1 wherein said method is utilised to determine the spatial variation of at least one of the following properties: absorber layer quality; minority carrier lifetime; homogeneity of layer composition in compound materials; impurity concentration; concentration of electrical defects; and concentration of structural defects.

6. A method as claimed in claim 1 wherein said method is utilised to monitor the production of thin film-based photovoltaic cells or modules.

7. A method as claimed in claim 6 wherein said method is utilised to monitor at least one of: minority carrier lifetime variations; local voltage variations upon illumination; local shunted areas or shunted individual cells in an interconnected module; or series resistance problems in a cell or module.

8. A method as claimed in claim 1 wherein said method further comprises the step of (e) utilising the information determined in step (d) to adjust said thin film deposition process.

9. A method as claimed in claim 8 wherein step (e) includes at least one of: removal of thin film samples; adjustment of a processing condition; or detection of a hardware fault in the deposition process.

10. A method as claimed in claim 1 wherein said method further comprises the step of (f) utilising the information determined in step (d) to adjust or control post-deposition processing of said thin film.

11. A method as claimed in claim 10 wherein said post-deposition processing includes annealing, hydrogenation, diffusion, laser isolation of a defective area, metallisation, module interconnection, or reprocessing of the thin film.

12. A method as claimed in claim 1 wherein said photoluminescence includes the band-to-band luminescence of said semiconductor thin film.

13. A method as claimed in claim 1 wherein said photoluminescence includes luminescence emitted by impurities and defects in said semiconductor thin film.

14. An apparatus when used to implement the method of claim 1.

15. A method of monitoring a partially or fully completed semiconductor thin film photovoltaic cell or module, said method comprising the steps of:
(a) illuminating with a predetermined illumination an area of said semiconductor thin film photovoltaic cell or module, to produce photoluminescence from said cell or module;
(b) capturing an image of said photoluminescence;
(c) processing said image to determine one or more properties of said cell or module; and
(d) using said one or more properties to infer information about cell or module.

16. A method as claimed in claim 15, wherein said information includes the spatial variation of at least one of the following properties: absorber layer quality; minority carrier lifetime; homogeneity of layer composition in compound materials; impurity concentration; concentration of electrical defects;
and concentration of structural defects.

17. A method as claimed in claim 15, wherein said information includes local voltage variations upon illumination; local shunted areas or shunted individual cells in an interconnected module; or series resistance problems in a cell or module.

18. A method as claimed in claim 15, wherein said method further comprises the step of (e) utilising the information determined in step (d) to adjust the process used to deposit the thin film in said semiconductor thin film photovoltaic cell or module.

19. A method as claimed in claim 18 wherein step (e) includes at least one of: removal of thin film samples; adjustment of a processing condition; or
detection of a hardware fault in the deposition process.

20. A method as claimed in claim 15 wherein said method further comprises the step of (f) utilising the information determined in step (d) to adjust or control further processing of said semiconductor thin film photovoltaic cell or module.

21. A method as claimed in claim 20 wherein said further processing includes annealing, hydrogenation, diffusion, laser isolation of a defective area, metallisation, module interconnection, or reprocessing of the thin film.

22. A method as claimed in claim 15, wherein said method further includes the step of (g) predicting the performance of a finished semiconductor thin film photovoltaic cell or module.

23. An apparatus when used to implement the method of claim 15.
